(19) United States
(12) Patent Application Publication
(10) Pub. No.: US 2022/0359424 A1
(43) Pub. Date: Nov. 10, 2022

(54) SEMICONDUCTOR DEVICE

(71) Applicant: Samsung Electronics Co., Ltd., Suwon-si (KR)

(72) Inventors: Jeongseop SHIM, Suwon-si (KR); Jihye PARK, Hwaseong-si (KR); Wangi SOHN, Hwaseong-si (KR); Eunshoo HAN, Hwaseong-si (KR)

(73) Assignee: Samsung Electronics Co., Ltd., Suwon-si (KR)

(21) Appl. No.: 17/734,234

(22) Filed: May 2, 2022

(30) Foreign Application Priority Data
May 6, 2021 (KR) 10-2021-0058822

(51) Int. Cl. H01L 23/00; H01L 27/11556; H01L 27/11529; H01L 27/11582; H01L 27/11573

(52) U.S. Cl. CPC H01L 23/562; H01L 27/11556; H01L 27/11529; H01L 27/11582; H01L 27/11573

(57) ABSTRACT

A semiconductor memory device may include a substrate, a plurality of lower electrodes on the substrate, and a support structure. The plurality of lower electrodes may extend in a first direction perpendicular to a top surface of the substrate. The support structure may have a flat panel shape. The support structure may contact a side surface of the plurality of lower electrodes and may support the plurality of lower electrodes. The support structure may include a plurality of openings. The support structure may include a first part and a second part. The first part may include the plurality of openings repeated by a first pitch. The second part may include the plurality of openings repeated by a second pitch that is different from the first pitch.

### CROSS-REFERENCE TO RELATED APPLICATION

This application is based on and claims priority under 35 U.S.C. § 119 to Korean Patent Application No. 10-2021-0058822, filed on May 6, 2021 in the Korean Intellectual Property Office, the disclosure of which is incorporated by reference herein in its entirety.

### BACKGROUND

Inventive concepts relate to a semiconductor device.

As the high integration of memory products accelerates with the recent rapid development of miniaturized semiconductor process technology, an area of a unit cell has been reduced and an operating voltage of a semiconductor device has been lowered. For example, in semiconductor devices such as dynamic random-access memory (DRAM) and NAND flash memory, an area occupied by a unit memory cell corresponding to 1 bit is reduced, causing a failure due to a process factor that has not caused the failure.

### SUMMARY

Inventive concepts provide a semiconductor device having improved reliability.

According to an embodiment of inventive concepts, a semiconductor device may include a substrate, a plurality of lower electrodes on the substrate, and a support structure. The plurality of lower electrodes may extend in a first direction perpendicular to a top surface of the substrate. The support structure may have a flat panel shape. The support structure may contact a side surface of the plurality of lower electrodes and may support the plurality of lower electrodes. The support structure may include a plurality of openings. The support structure may include a first part and a second part. The first part may include the plurality of openings repeated by a first pitch. The second part may include the plurality of openings repeated by a second pitch that is different from the first pitch.

According to an embodiment of inventive concepts, a semiconductor device may include a plurality of blocks. Each of the plurality of blocks may be a set memory unit and may include a plurality of lower electrodes and a support structure. The plurality of lower electrodes may extend in a first direction. The support structure has a flat panel shape. The support structure may contact a side surface of the plurality of lower electrodes and may support the plurality of lower electrodes. The support structure may include a plurality of openings. Each of the plurality of blocks may have a center portion where the plurality of openings may be repeated by a first pitch and an edge portion where the plurality of opening may be repeated by a second pitch. The first pitch may be less than the second pitch. The edge portion may surround the center portion.

According to an embodiment of inventive concepts, a semiconductor device may include a substrate, a plurality of gate electrodes stacked on the substrate in a first direction perpendicular to a top surface of the substrate, a plurality of insulation films between the plurality of gate electrodes, a plurality of channel structures passing through the plurality of gate electrodes and the plurality of insulation films, and a plurality of bit lines extending in a second direction parallel to the top surface of the substrate on the plurality of channel structures. The plurality of bit lines may be connected to at least a part of the plurality of channel structures. The plurality of bit lines may include first bit lines and second bit lines. The first bit lines may be repeated with a first pitch in a third direction that is perpendicular to the first direction and the second direction. The second bit lines may be repeated with a second pitch that is different from the first pitch in the third direction.

### BRIEF DESCRIPTION OF THE DRAWINGS

Embodiments of inventive concepts will be more clearly understood from the following detailed description taken in conjunction with the accompanying drawings in which:

FIG. 1 illustrates a layout of a semiconductor device according to embodiments of inventive concepts;

FIG. 2 illustrates a layout of an internal block of FIG. 1;

FIG. 3 is a partial plane view enlarging a part of a center portion of an internal block of FIG. 2;

FIG. 4 is a cross-sectional view taken along a cut line XX-XX′ of FIG. 3;

FIG. 5 is a partial plane view enlarging a part of an edge portion of an internal block of FIG. 2;

FIG. 6 is a partial plane view corresponding to FIG. 3, illustrating a part of a corner block;

FIG. 7 is a partial plane view corresponding to FIG. 5, illustrating a part of a corner block BLKC;

FIG. 8 illustrates a layout for describing a semiconductor device according to other embodiments of inventive concepts;

FIG. 9 illustrates a layout of a semiconductor device according to other embodiments of inventive concepts;

FIG. 10 is a plane view of a part of a center portion of FIG. 9;

FIG. 11 is a cross-sectional view taken along a cut line YY-YY′ of FIG. 10; and

FIG. 12 is a plane view of a part of an edge portion of FIG. 9.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, embodiments of inventive concepts will be described in detail with reference to the accompanying drawings. Like components in the drawings will be referred to as like reference numerals, and will not be repeatedly described.

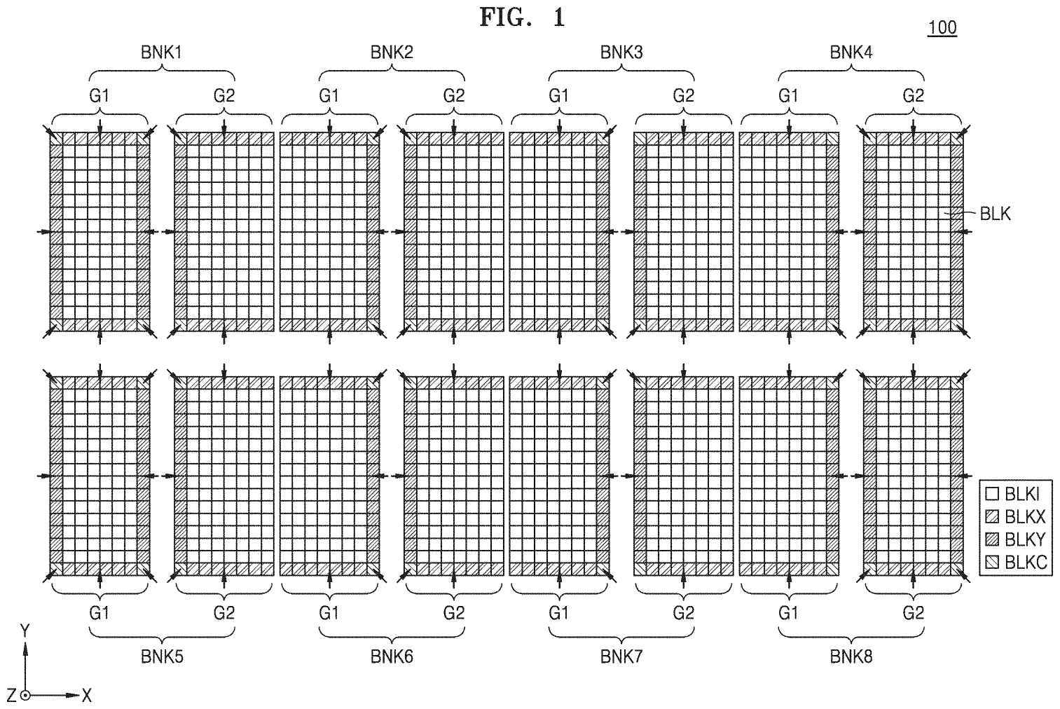

FIG. 1 illustrates a layout of a semiconductor device 100 according to embodiments of inventive concepts.

Referring to FIG. 1, the semiconductor device 100 may include first through eighth banks BNK1, BNK2, BNK3, BNK4, BNK5, BNK6, BNK7, and BNK8. The first through eighth banks BNK1 through BNK8 are split regions sequentially operating inside a memory device in the semiconductor device 100.

Each of the first through eighth banks BNK1 through BNK8 may include a first group G1 and a second group G2. Between the first group G1 and the second group G2, a control circuit for controlling each of the first through eighth banks BNK1 through BNK8 may be arranged. That is, the first group G1 and the second group G2 may be separated from each other with the control circuit therebetween, and the first group G1 and the second group G2 included in any one of the first through eighth banks BNK1 through BNK8 may be controlled by the same control circuit.

The first group G1 and the second group G2 may include a plurality of blocks BLK. The blocks BLK may include a plurality of memory cells, respectively. Each of the plurality of memory cells may store, but not limited to, 1-bit memory. The plurality of memory cells may be, for example, multi-level cells, and may store memory of 1 bit or more. Each block BLK may be, for example, a unit memory block having a capacity of about 1 MB. For convenience of description, the blocks BLK may be classified into internal blocks BLKI, first edge blocks BLKX, second edge blocks BLKY, and corner blocks BLKC. The internal blocks BLKI, the first edge blocks BLKX, the second edge blocks BLKY, and the corner blocks BLKC may have substantially the same circuit layout and have different optical proximity correction (OPC) rules applied thereto.

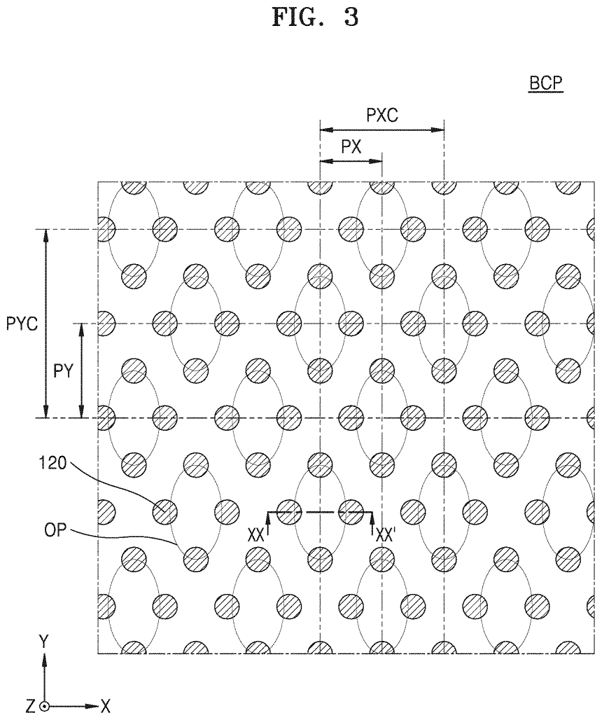

The different OPC rules may include a gradual bias and a macro bias that will be described in more detail with reference to FIGS. 3 through 6. Herein, the gradual bias is intended to correct bending of a hole, occurring in a process of depositing materials into a plurality of holes having a small pitch and a large aspect ratio. A pitch of a particular component may mean a unit length in which the component is repeatedly provided. The macro bias is intended to correct the edge effect caused by the asymmetry of a layout in a boundary between the first group G1 and the second group G2.

For example, the gradual bias may be applied to the internal blocks BLKI. The gradual bias and the macro bias may be applied to the first edge blocks BLKX, the second edge blocks BLKY, and the corner blocks BLKC.

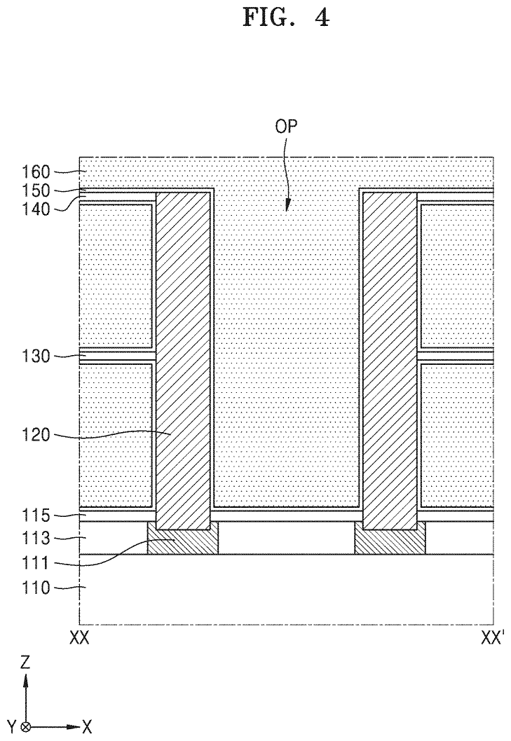

Two directions that are parallel to a top surface of a substrate 110 (see FIG. 4) included in the semiconductor device 100 and are perpendicular to each other may be defined as an X direction and a Y direction, and a direction perpendicular to the top surface may be defined as a Z direction.

For example, the second group G2 of the first bank BNK1 may be arranged adjacent to the first group G1 of the second bank BNK2. An X-direction distance between the first group G1 of the first bank BNK1 and the second group G2 of the first bank BNK1 may be greater than an X-direction distance between the second group G2 of the first bank BNK1 and the first group G1 of the second bank BNK2. Thus, the second edge blocks BLKY may be arranged in each of opposite edges, which are parallel to the Y direction, of the first group G1 of the first bank BNK1. And the second edge blocks BLKY may be arranged in one, which is adjacent to the first group G1, of the edges, which are parallel to the Y direction, of the second group G2 of the first bank BNK1.

That is, the macro bias may not be applied based on the first through eighth banks BNK1 through BNK8 that are operating units of the semiconductor device 100, and may be applied based on an interval between the first group G1 and the second group G2 (more specifically, an interval between the blocks BLK).

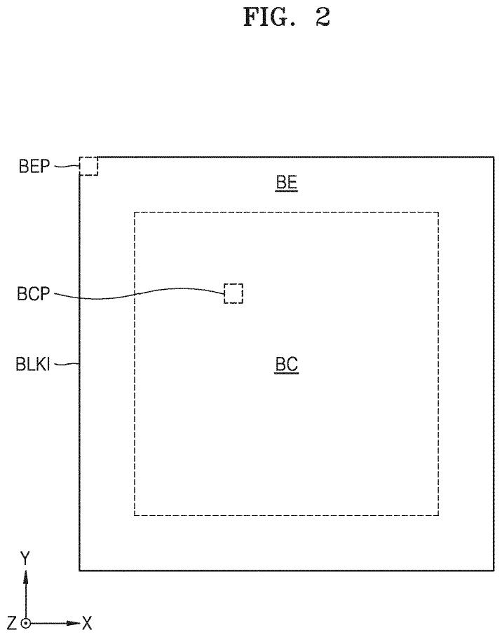

FIG. 2 illustrates a layout of the internal block BLKI of FIG. 1.

Referring to FIG. 2, the internal block BLKI may include a center portion BC and an edge portion BE surrounding the center portion BC. According to embodiments of inventive concepts, the gradual bias may be applied to the edge portion BE and the gradual bias may not be applied to the center portion BC.

In the internal blocks BLKI, memory device cells corresponding to a set capacity unit (e.g., about 1 MB) may be arranged. A description of a capacity unit and a layout of the internal block BLKI may be applied similarly to the first edge blocks BLKX, the second edge blocks BLKY, and the corner blocks BLKC of FIG. 1.

FIG. 3 is a partial plane view enlarging a part BCP of the center portion BC of the internal block BLKI of FIG. 2.

FIG. 4 is a cross-sectional view taken along a cut line XX-XX′ of FIG. 3.

Referring to FIGS. 3 and 4, the semiconductor device 100 may include the substrate 110, an interlayer insulation film 113, an etch stop film 115, a plurality of lower electrodes 120, a first support structure 130, a second support structure 140, a dielectric layer 150, and an upper electrode 160.

The substrate 110 may include a semiconductor material such as, for example, silicon, germanium, silicon-germanium, etc., and may further include an epitaxial layer, a silicon on insulator (SOI) layer, a germanium on insulator (GOI) layer, a semiconductor on insulator (SeOI) layer, etc. The substrate 110 may include semiconductor elements for driving memory cells configured by the plurality of lower electrodes 120 and the upper electrode 160. For example, the semiconductor elements may include metal-oxide-semiconductor (MOS) transistors, diodes, and resistors.

The interlayer insulation film 113 may include a high-density plasma (HDP) oxide film, tetraethyl orthosilicate (TEOS), plasma enhanced tetraethyl orthosilicate (PE-TEOS), O3-tetraethyl orthosilicate (O3-TEOS), undoped silicate glass (USG), phosphosilicate glass (PSG), borosilicate glass (BSG), borophosphosilicate glass (BPSG), fluoride silicate glass (FSG), spin on glass (SOG), tonen silazene (TOSZ), or a combination thereof. In addition, the interlayer insulation film 113 may include silicon nitride, silicon oxynitride, or a material having a low dielectric constant, e.g., a material having a lower dielectric constant than silicon oxide.

The etch stop film 115 may be formed of a material having etching selectivity to the interlayer insulation film 113, which is planarized. For example, the etch stop film 115 may be formed of silicon nitride or silicon oxynitride.

The plurality of lower electrodes 120 may include at least one of metal materials, metal nitride, or metal silicide. For example, the plurality of lower electrodes 120 may include refractory metal materials such as cobalt, titanium, nickel, tungsten, and molybdenum. In another example, the plurality of lower electrodes 120 may include metal nitrides such as titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), and tungsten nitride (WN). The plurality of lower electrodes 120 may include at least one noble metal material selected from a group consisting of platinum (Pt), ruthenium (Ru), and iridium (Ir). The plurality of lower electrodes 120 may include noble metal oxide.

On the substrate 110, the plurality of lower electrodes 120 may have a pillar shape extending in a direction perpendicular to a top surface of the substrate 110. Cross-sections of the lower electrodes 120 may be circular or oval.

The plurality of lower electrodes 120 may be arranged in the X direction and the Y direction to constitute multiple rows and columns. In this case, to secure a space between the plurality of lower electrodes 120, the plurality of lower electrodes 120 constituting any one row may be arranged alternately with the plurality of lower electrodes 120 constituting another adjacent row. Thus, a space efficiently large to provide a dielectric material for forming the dielectric layer 150 may be provided between the plurality of lower electrodes 120.

According to some embodiments of inventive concepts, the plurality of lower electrodes 120 may form a honeycomb structure in which the plurality of lower electrodes 120 are arranged at vertices and center points of a plurality of hexagons filling a two-dimensional plane. Each of six vertices of each of the hexagons constituting the honeycomb structure may be a center point of each of six other hexagons arranged adjacent to the hexagons, in which a center point of a hexagon may be a vertex shared among six hexagons.

As the plurality of lower electrodes 120 are arranged in the honeycomb structure, a constant interval may be maintained between the plurality of lower electrodes 120, such that a dielectric material and an upper electrode material may be deposited uniformly in a subsequent process.

In an embodiment of inventive concepts, the plurality of lower electrodes 120 may have a high aspect ratio, resulting in the collapse of the plurality of lower electrodes 120 and thus causing a defect. According to embodiments of inventive concepts, as the first support structure 130 and the second support structure 140 support the plurality of lower electrodes 120, the collapse of the plurality of lower electrodes 120 may be limited and/or prevented and thus the defect of the semiconductor device 100 may also be limited and/or prevented.

According to embodiments of inventive concepts, the first support structure 130 and the second support structure 140 may include, but not limited to, silicon nitride. The semiconductor device 100 is illustrated as including, but not limited to, two support structures, that is, the first and second support structures 130 and 140. For example, the semiconductor device 100 may include any one of the first support structure 130 and the second support structure 140 or may further include an additional support structure.

The first support structure 130 and the second support structure 140 may be formed as a one-body type including a plurality of openings OP. Each of the openings OP of the first support structure 130 may overlap any corresponding one of the openings OP of the second support structure 140 in the Z direction. The first support structure 130 and the second support structure 140 may have a flat panel shape separated from the top surface of the substrate 110. The first support structure 130 may be arranged between the second support structure 140 and the top surface of the substrate 110.

The plurality of openings OP may be arranged in the X direction and the Y direction. According to embodiments of inventive concepts, the plurality of openings OP may have an oval shape and may be arranged such that a center of each of the plurality of openings OP overlaps a center of a diamond including four adjacent lower electrodes 120. In this case, each of the plurality of openings OP may expose four lower electrodes 120.

However, inventive concepts are not limited thereto, and the planar shape of each of the plurality of openings may be circular, and the center of each of the plurality of openings may overlap the center of an equilateral triangle including three adjacent lower electrodes 120. When the planar shape of each of the plurality of openings OP is circular, each of the plurality of openings OP may expose three lower electrodes 120.

Herein, when the plurality of openings OP expose the plurality of lower electrodes 120, it may mean that the first support structure 130 and the second support structure 140 before deposition of the dielectric layer 150 and the upper electrode 160 expose a part of the plurality of lower electrodes 120.

The dielectric layer 150 may include, for example, any one single film selected from a combination of metal oxide such as HfO₂, ZrO₂, Al₂O₃, La₂O₃, Ta₂O₃, and TiO₂ and a dielectric material with a perovskite structure such as SrTiO₃(STO), BaTiO₃, PZT, and PLZT, or a combination thereof.

The upper electrode 160 may include at least one of silicon, metal materials, metal nitride films, or metal silicide, doped with impurities. The upper electrode 160 may include, but not limited to, the same material as the plurality of lower electrodes 120.

According to embodiments of inventive concepts, in the part BCP of the center portion BC, an X-direction pitch PXC of the plurality of openings OP may be about twice an X-direction pitch PX of the plurality of lower electrodes 120, and a Y-direction pitch PYC of the plurality of openings OP may be about twice a Y-direction pitch PY of the plurality of lower electrodes 120.

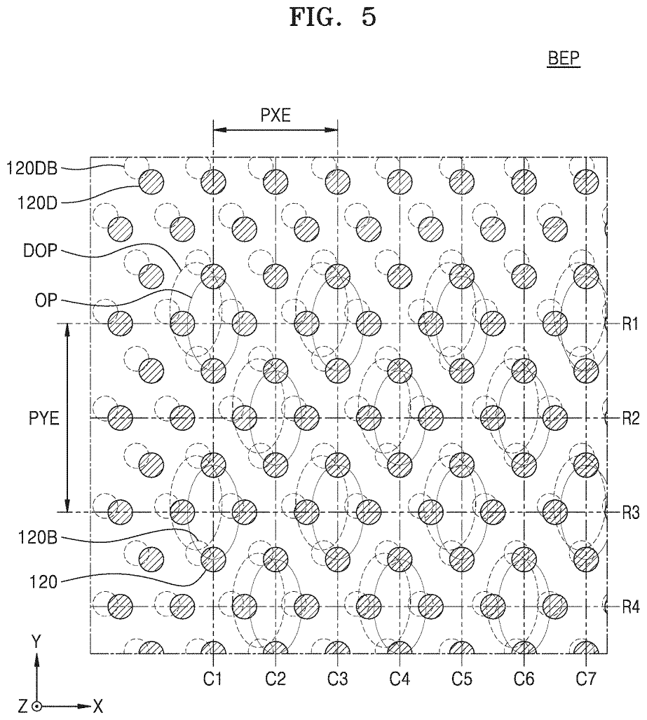

FIG. 5 is a partial plane view enlarging a part BEP of the edge portion BE of the internal block BLKI of FIG. 2.

In FIG. 5, a plurality of designed positions 120B corresponding to the plurality of lower electrodes 120 are indicated by broken lines adjacent to the plurality of lower electrodes 120, respectively. According to embodiments of inventive concepts, the designed positions 120B may be substantially the same as positions of bottom surfaces of the plurality of lower electrodes 120. Likewise, in FIG. 5, designed positions DOP of the plurality of openings OP, which correspond to the plurality of designed positions 120B of the plurality of lower electrodes 120, are indicated by broken lines in FIG. 5.

Referring to FIGS. 2 and 5, after a plurality of holes for forming the plurality of lower electrodes 120 are provided, when a conductive material constituting the plurality of lower electrodes 120 is deposited in the holes, the lower electrodes 120 may bend in a process of deposition. Thus, even when a lithography process of forming the plurality of holes is performed based on accurate alignment, an offset may occur between the designed positions 120B and actual positions (e.g., positions of top surfaces) of the lower electrodes 120 in a process of providing a material constituting the lower electrodes 120.

The plurality of openings OP may be formed in positions biased from the designed positions DOP. An X-direction bias and a Y-direction bias of the plurality of openings OP may change depending on the positions of the plurality of openings OP.

Due to the X-direction bias and the Y-direction bias of the plurality of openings OP, the center of each of the plurality of openings OP may overlap a corresponding one of centers of diamonds formed by top surfaces of four adjacent lower electrodes 120 in the Z direction and may not overlap a corresponding one of centers of diamonds formed by the designed positions 120B of the top surfaces of the four adjacent lower electrodes 120. Here, when the four lower electrodes 120 transferred to the actual circuit based on each of the four designed positions 120B constituting one of the diamonds are exposed by one of the plurality of openings OP, it may be referred that one of the plurality of openings OP corresponds to the one of the diamonds. Herein, each of the centers of the diamonds formed by the designed positions 120B of the top surfaces of the four adjacent lower electrodes 120 may be substantially the same as each of the centers of the diamonds formed by designed positions of bottom surfaces of the four adjacent lower electrodes 120.

A bias of the openings OP arranged relatively close to the center portion BC of the internal block BLKI among the plurality of openings OP may be smaller than a bias of the openings OP arranged relatively far from the center portion BC of the internal block BLKI among the plurality of openings OP. Herein, the bias may mean a magnitude of movement from a position designed in rule-based OPC.

The plurality of openings OP may be arranged to form a plurality of rows R1, R2, R3, and R4 and a plurality of columns C1, C2, C3, C4, C5, C6, and C7. The first row R1 may be farthest from the center portion BC among the plurality of rows R1 through R4, and the first column C1 may be farthest from the center portion BC among the plurality of columns C1 through C7. That is, a direction from the first row R1 toward the fourth row R4 and a direction from the first column C1 toward the seventh column C7 may be directions from the edge portion BE of the internal block BLKI towards the center portion BC.

For example, the Y-direction bias of the openings OP belonging to preceding ones among the plurality of rows R1 through R4 may be greater than the Y-direction bias of the openings OP belonging to following ones among the plurality of rows R1 through R4. More specifically, the Y-direction bias of the openings OP of the first row R1 may be greater than the Y-direction bias of the openings OP of the second row R2, and the Y-direction bias of the openings OP of the second row R2 may be greater than the Y-direction bias of the openings OP of the third row R3. A Y-direction bias BY(n) of the openings OP of an n^{th} row may be determined according to Equation 1.

BY(n)=BY0−(n−1)ΔY [Equation 1]

In Equation 1, BY0 indicates the Y-direction bias of the openings OP of the first row R1, and ΔY indicates a difference between Y-direction biases of adjacent ones of the rows R1 through R4.

Thus, a Y-direction pitch PYE of the openings OP of the edge portion BE may be reduced as compared to the Y-direction pitch PYC (see FIG. 3) of the openings OP of the center portion BC. A relationship between the Y-direction pitch PYE of the openings OP of the edge portion BE and the Y-direction pitch PYC (see FIG. 3) of the openings OP of the center portion BC may be expressed as below. Herein, the Y-direction pitch PYC (see FIG. 3) of the openings OP of the center portion BC may be substantially the same as the Y-direction pitch of the designed positions DOP of the plurality of openings OP.

PYE=PYC−ΔY [Equation 2]

Likewise, the X-direction bias of the openings OP belonging to preceding ones among the plurality of columns C1 through C7 may be greater than that of the openings OP belonging to following ones among the plurality of columns C1 through C7. More specifically, the X-direction bias of the openings OP of the first column C1 may be greater than the X-direction bias of the openings OP of the second column C2, and the X-direction bias of the openings OP of the second column C2 may be greater than the X-direction bias of the openings OP of the third column C3. An X-direction bias BX(n) of the openings OP of an n^{th} column may be determined according to Equation 3.

BX(n)=BX0−(n−1)ΔX [Equation 3]

In Equation 3, BX0 indicates the X-direction bias of the openings OP of the first column C1, and ΔX indicates a difference between X-direction biases of adjacent ones of the columns C1 through C7.

Thus, an X-direction pitch PXE of the openings OP of the edge portion BE may be reduced as compared to the X-direction pitch PXC (see FIG. 3) of the openings OP of the center portion BC. A relationship between the X-direction pitch PXE of the openings OP of the edge portion BE and the X-direction pitch PXC (see FIG. 3) of the openings OP of the center portion BC may be expressed as below. Herein, the X-direction pitch PXC (see FIG. 3) of the openings OP of the center portion BC may be substantially the same as the X-direction pitch of the designed positions DOP of the plurality of openings OP.

PXE=PXC−ΔX [Equation 4]

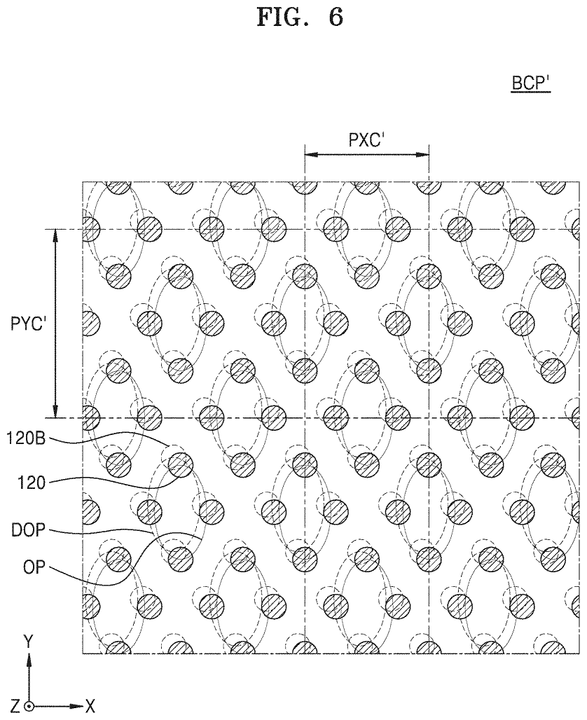

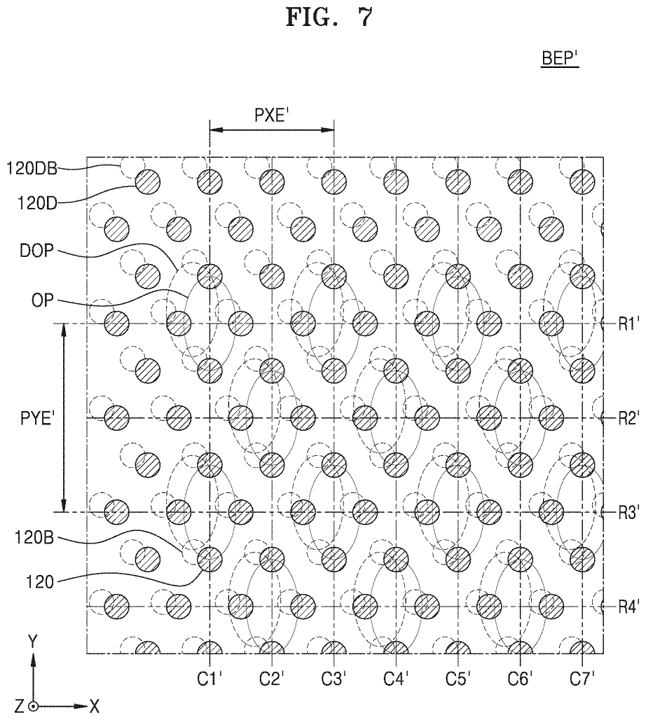

The bias described above with reference to Equations 1 through 4 may be indicated as the gradual bias for distinguishing from the bias described with reference to FIGS. 6 and 7.

According to embodiments of inventive concepts, considering mis-alignment caused by a material deposition process of forming the plurality of lower electrodes 120, rule-based OPC that applies the X-direction bias and the Y-direction bias, which depend on the designed positions DOP of the plurality of openings OP, may be performed before a lithography process is performed. Thus, non-formation of the dielectric layer 150 and the upper electrode 160 due to non-exposing of some of the lower electrodes 120 may be limited and/or prevented and the reliability of the semiconductor device 100 may be improved.

The semiconductor device 100 may further include dummy lower electrodes 120D that are not exposed by the plurality of openings OP. According to embodiments of inventive concepts, the dummy lower electrodes 120D may be arranged in positions that are offset from designed positions 120DB, similarly with the lower electrodes 120.

According to embodiments of inventive concepts, the first support structure 130 and the second support structure 140 may be formed across the entire internal block BLKI. Accordingly, each of the first and second support structures 130 and 140 may include a first portion (e.g., portion BC) in which the plurality of openings OP have a first pitch (e.g., X-direction pitch PXC and Y-direction pitch PYC) and a second portion (e.g., portion BE) in which the plurality of openings OP have a second pitch (for example, pitch in X direction (PXE) and pitch in Y direction (PYE)).

FIG. 6 is a partial plane view corresponding to FIG. 3, illustrating a part BCP′ of the corner block BLKC.

FIG. 7 is a partial plane view corresponding to FIG. 5, illustrating a part BEP′ of the corner block BLKC.

For convenience of description, description redundant with the description made with reference to FIGS. 3 through 5 will be omitted and a difference will be described mainly.

Referring to FIGS. 1, 3, and 6, the openings OP of the part BCP′ of the corner block BLKC may be biased from the designed positions DOP, unlike the openings OP of the part BCP of the internal block BLKI. Each of the openings OP included in the part BCP′ may be biased by the same distance in the X direction and by the same distance in the Y direction. For convenience of description, such a bias will be denoted as the macro bias.

Thus, unlike in the part BCP of the internal block BLKI, the center of each of the plurality of openings OP of the part BCP′ of the corner block BLKC may overlap a corresponding one of centers of diamonds formed by top surfaces of four adjacent lower electrodes 120 in the Z direction and may not overlap a corresponding one of centers of diamonds formed by the designed positions 120B of the top surfaces of the four adjacent lower electrodes 120.

According to embodiments of inventive concepts, an X-direction pitch PXC′ and a Y-direction pitch PYC′ of the openings OP included in the part BCP′ may be the same as designed pitches, in spite of the macro bias. In other words, the X-direction pitch PXC′ of the openings OP included in the part BCP′ may be the same as the X-direction pitch PXC of the openings OP included in the part BCP, and the Y-direction pitch PYC′ of the openings OP included in the part BCP′ may be the same as the Y-direction pitch PYC of the openings OP included in the part BCP.

According to embodiments of inventive concepts, the openings OP included in the part BCP′ of the corner block BLKC may be biased in the X direction and the Y direction, respectively. This is intended to correct the offset of the lower electrodes 120 of the corner block BLKC, which occurs due to the asymmetry of the boundary between the first group G1 and the second group G2.

Directions of the macro biases of the corner blocks BLKC, the first edge blocks BLKX, and the second edge blocks BLKY are indicated by arrows in FIG. 1. The direction of the macro bias may be toward the center from the boundary between the first group G1 and the second group G2. More specifically, the directions of the macro biases of the corner blocks BLKC may be toward the corner blocks BLKC arranged in a diagonal direction, and the bias directions of the first edge blocks BLKX may be the Y direction and the bias directions of the second edge blocks BLKY may be the X direction.

Referring to FIGS. 1, 3, and 7, the gradual bias may be applied to the openings OP included in the part BEP′ of the corner block BLKC, like the part BEP of the internal block BLKI. The macro bias described with reference to FIGS. 1, 3, and 6 as well as the gradual bias may be applied to the openings OP included in the part BEP′ of the corner block BLKC.

The openings OP included in the part BEP′ of the corner block BLKC may constitute rows R1′, R2′, R3′, and R4′ and columns C1, C2′, C3′, C4′, C5′, C6′, and C7′, like in FIG. 5.

A Y-direction bias BY′(n) of the openings OP included in the n^{th} row of the part BEP′ of the corner block BLKC may follow Equation 5.

BY′(n)=BY0−(n−1)ΔY+MY [Equation 5]

Herein, MY indicates a magnitude of the macro bias in the Y direction.

Thus, a Y-direction pitch PYE′ of the openings OP of the part BEP′ of the corner block BLKC may be as below.

PYE′=PYC−ΔY [Equation 6]

That is, the Y-direction pitch PYE′ of the openings OP of the part BEP′ of the corner block BLKC may be substantially the same as the Y-direction pitch PYE of the openings OP of the part BEP of the internal block BLKI.

An X-direction bias BX′(n) of the openings OP included in the n^{th} column of the part BEV of the corner block BLKC may follow Equation 7.

BX′(n)=BX0−(n−1)ΔX+MX [Equation 7]

Herein, MX indicates a magnitude of the macro bias in the X direction.

Thus, the X-direction pitch PXE′ of the openings OP of the part BEV of the corner block BLKC may be as below.

PXE′=PXC−ΔX [Equation 8]

That is, the X-direction pitch PXE′ of the openings OP of the part BEV of the corner block BLKC may be substantially the same as the X-direction pitch PXE of the openings OP of the part BEP of the internal block BLKI.

That is, the gradual bias and the macro bias may not be applied to the part BCP of the internal block BLKI, and the gradual bias may be applied to and the macro bias may not be applied to the part BEP.

In addition, the macro bias may be applied to, but the gradual bias may not be applied to, the first edge block BLKX and the second edge block BLKY and the part BCP′ of the corner blocks BLKC, and the gradual bias and the macro bias may be applied to the part BEP′, respectively.

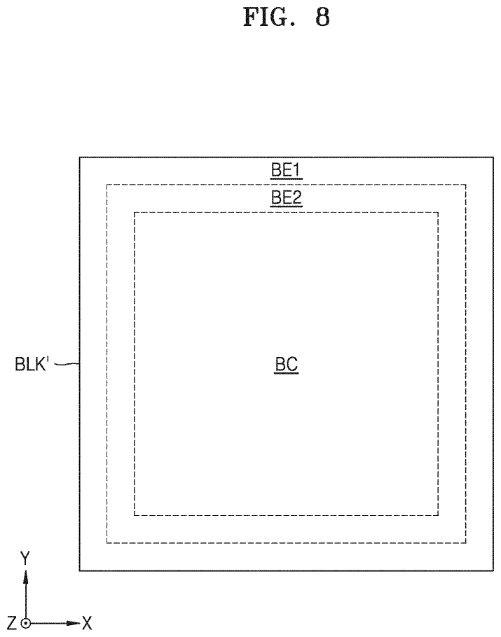

FIG. 8 illustrates a layout for describing a semiconductor memory device according to other embodiments of inventive concepts.

For convenience of description, description redundant with the description made with reference to FIGS. 1 through 7 will be omitted and a difference will be described mainly.

Referring to FIG. 8, an internal block BLK′ may include a center portion BC, a first edge portion BE1 surrounding the center portion BC, and a second edge portion BE2 between the first edge portion BE1 and the center portion BC.

According to embodiments of inventive concepts, a Y-direction bias BY1(n) of openings OP (see FIG. 5) included in an n^{th} row of the first edge portion BE1 and an X-direction bias BX1(n) of openings OP (see FIG. 5) included in an n^{th} column of the first edge portion BE1 may follow Equation 9.

BY1(n)=BY1−(n−1)ΔY1

BX1(n)=BX1−(n−1)ΔX1 [Equation 9]

Herein, BY1 indicates a Y-direction bias of openings OP (see FIG. 5) included in a first row of the first edge portion BE1, and ΔY1 indicates a difference in Y-direction bias between adjacent rows. BX1 indicates an X-direction bias of openings OP (see FIG. 5) included in a first column of the first edge portion BE1, and ΔX1 indicates a difference in X-direction bias between adjacent columns.

According to embodiments of inventive concepts, a Y-direction bias BY2(n) of openings OP (see FIG. 5) included in an n^{th} row of the second edge portion BE2 and an X-direction bias BX2(n) of openings OP (see FIG. 5) included in an n^{th} column of the second edge portion BE2 may follow Equation 10.

BY2(n)=BY2−(n−1)ΔY2

BX2(n)=BX2−(n−1)ΔX2 [Equation 10]

Herein, BY2 indicates a Y-direction bias of openings OP (see FIG. 5) included in a first row of the second edge portion BE2, and ΔY2 indicates a difference in Y-direction bias between adjacent rows. BX2 indicates an X-direction bias of openings OP (see FIG. 5) included in a first column of the second edge portion BE2, and ΔX2 indicates a difference in X-direction bias between adjacent columns.

According to embodiments of inventive concepts, differences between biases of the first edge portion BEL ΔX1 and ΔY1, may be different from differences between biases of the second edge portion BE2, ΔX2 and ΔY2. For example, ΔX1 may be greater than ΔX2, and ΔY1 may be greater than ΔY2. In another example, ΔX2 may be greater than ΔX1, and ΔY2 may be greater than ΔY1.

According to embodiments of inventive concepts, the X-direction pitch PXE1 and the Y-direction pitch PYE1 of the first edge portion BE1 may follow Equation 11.

PXE1=PXC−ΔX1

PYE1=PYC−ΔY1 [Equation 11]

Likewise, the X-direction pitch PXE2 and the Y-direction pitch PYE2 of the second edge portion BE2 may follow Equation 12.

PXE2=PXC−ΔX2

PYE2=PYC−ΔY2 [Equation 11]

According to embodiments of inventive concepts, the X-direction pitch PXE1 may be different from the X-direction pitch PXE2, and the Y-direction pitch PYE1 may be different from the Y-direction pitch PYE2. For example, the X-direction pitch PXE1 may be greater than the X-direction pitch PXE2, and the Y-direction pitch PYE1 may be greater than the Y-direction pitch PYE2. In another example, the X-direction pitch PXE2 may be greater than the X-direction pitch PXE1, and the Y-direction pitch PYE2 may be greater than the Y-direction pitch PYE1.

Those of ordinary skill in the art may easily reach a block to which three or more different gradual biases are applied based on an embodiment of inventive concepts described with reference to FIG. 8.

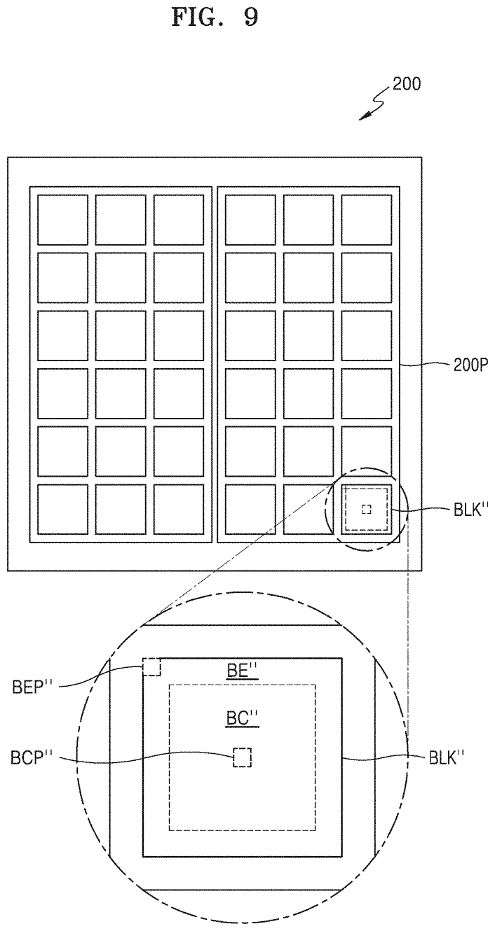

FIG. 9 illustrates a layout of a semiconductor device 200 according to other embodiments of inventive concepts.

Referring to FIG. 9, the semiconductor device 200 may be, for example, a quadrangular memory chip. The semiconductor device 200 may be, but no limited to, a NAND flash memory.

The semiconductor device 200 may include one or more planes 200P. In spite of some limitations, generally, the same concurrent operation may be performed in each of the planes 200P.

Each plane 200P may include a plurality of blocks BLK″. Herein, the block BLK″ may be the smallest unit capable of performing an erase operation, and may be a memory unit having the same circuit design. Each block BLK″ may include a plurality of pages. The plurality of pages may correspond to the smallest unit capable of performing a programming (e.g., a write) operation.

The plurality of blocks BLK″ may be a memory unit having a size that is set similar to FIG. 1. The plurality of blocks BLK″ may include a center portion BC″ and an edge portion BE″ surrounding the center portion BC″.

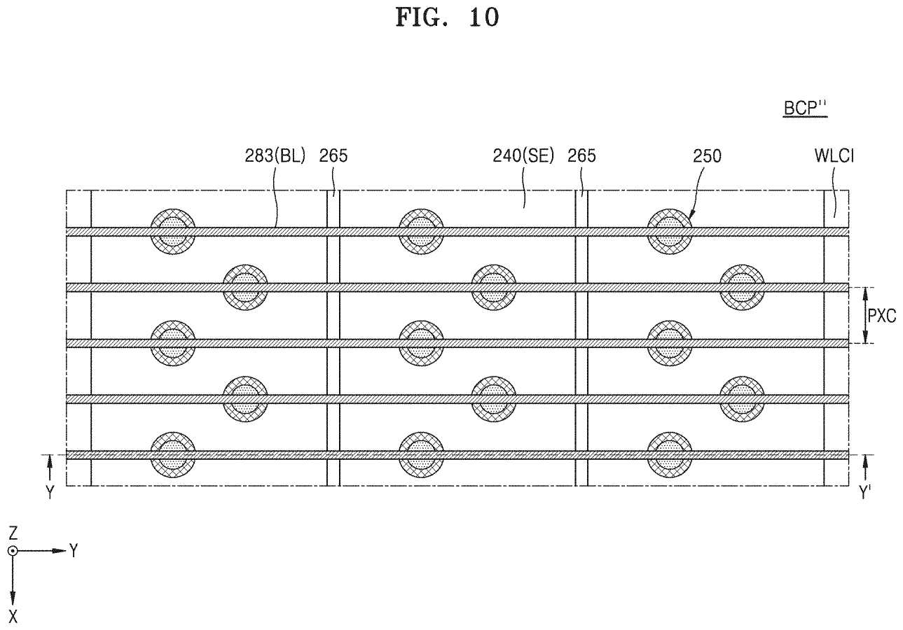

FIG. 10 is a plane view of a part BCP″ of the center portion BC″ of FIG. 9.

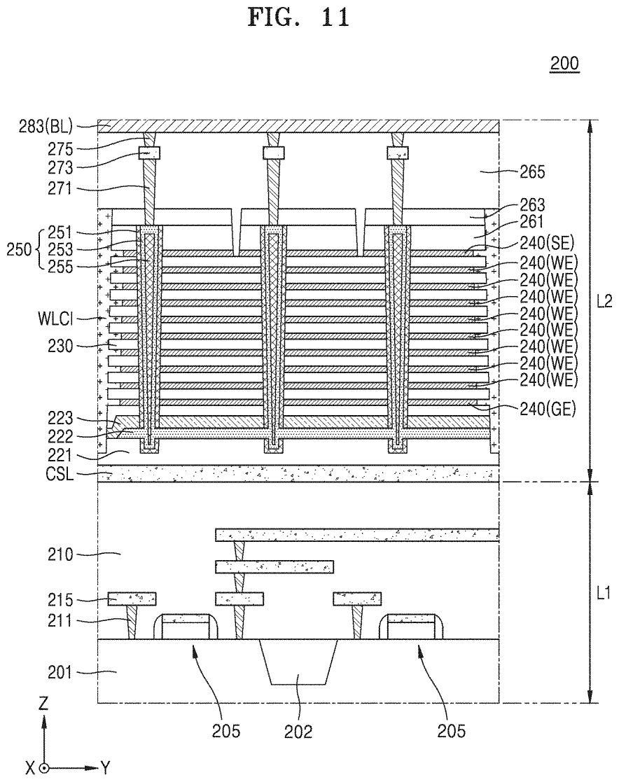

FIG. 11 is a cross-sectional view taken along a cut line YY-YY′ of FIG. 10.

Referring to FIGS. 10 and 11, a semiconductor memory device 10 may include a first semiconductor device layer L1 including a peripheral circuit and a second semiconductor device layer L2 including channel structures operating as a memory cell. The second semiconductor device layer L2 may be arranged on the first semiconductor device layer L1.

The first semiconductor device layer L1 may include a substrate 201, peripheral transistors 205 arranged on the substrate 201, a peripheral circuit line electrically connected to the peripheral transistors 205, and a lower insulation layer 210 covering the peripheral transistors 205 and the peripheral circuit line. According to some embodiments of inventive concepts, the lower insulation layer 210 may include an insulation material. According to some embodiments of inventive concepts, the lower insulation layer 210 may include, but not limited to, silicon oxide, silicon nitride, silicon oxynitride, etc.

According to some embodiments of inventive concepts, the substrate 201 may be a semiconductor substrate including a semiconductor material such as single crystal silicon or single crystal germanium. A trench for defining an active region and an inactive region and a device isolation film 202 filling the trench may be formed on the substrate 201. Herein, two directions that are parallel to a top surface of the substrate 201 and are perpendicular to each other may be defined as the X direction and the Y direction, and a direction perpendicular to the top surface of the substrate 201 may be defined as the Z direction.

According to some embodiments of inventive concepts, the peripheral transistors 111 and 112 may constitute a peripheral circuit for driving a memory cell of the second semiconductor device layer L2. According to some embodiments of inventive concepts, peripheral transistors 205 may constitute a control logic, a row decoder, a page buffer, and a common source line dry of a NAND flash memory.

The peripheral circuit line may include a plurality of peripheral conductive patterns 215 sequentially stacked on the substrate 201. The peripheral circuit line may further include a plurality of peripheral vias 211 connecting and the peripheral transistors 205 and the plurality of peripheral conductive patterns 215 formed in different levels. According to some embodiments of inventive concepts, the peripheral circuit line is illustrated as including the peripheral conductive patterns 215 of three layers and the peripheral vias 211 connecting them, but without being limited thereto, may include peripheral conductive lines of one layer, two layers, or four layers and vias connecting them.

According to some embodiments of inventive concepts, the peripheral conductive patterns 215 and the peripheral vias 211 may include a conductive material. According to some embodiments of inventive concepts, the peripheral conductive patterns 215 and the peripheral vias 211 may include tungsten, tantalum, cobalt, nickel, tungsten silicide, tantalum silicide, cobalt silicide, or nickel silicide. According to some embodiments of inventive concepts, the peripheral conductive patterns 215 and the peripheral vias 211 may include polysilicon.

The second semiconductor device layer L2 may include a common source line plate CSL, first through third semiconductor layers 221, 222, and 223 arranged on the common source line plate CSL, and insulation films 230, gate electrodes 240, and upper insulation films 261, 263, and 265, which are alternately and repeatedly stacked on the first through third semiconductor layers 221, 222, and 223. The second semiconductor device layer L2 may include channel structures 250, which pass through the insulation films 230 and the gate electrodes 240, and word line cut insulation films WLCI that separate the gate electrodes 240. According to some embodiments of inventive concepts, the second semiconductor device layer L2 may further include lines used for the gate electrodes 240 and the channel structures 250 passing through the gate electrodes 240 to operate as a memory cell array.

The common source line plate CSL may be arranged on the first semiconductor device layer L1. According to some embodiments of inventive concepts, the common source line plate CSL may have a flat panel shape. According to some embodiments of inventive concepts, the common source line plate CSL may include tungsten (W) or a tungsten (W) compound.

According to some embodiments of inventive concepts, the first through third semiconductor layers 221, 222, and 223 may be support layers supporting the insulation films 230 and the gate electrodes 240. According to some embodiments of inventive concepts, the first through third semiconductor layers 221, 222, and 223 may include, but not limited to, a plurality of layers.

According to some embodiments of inventive concepts, the first semiconductor layer 221 may be in contact with the second semiconductor layer 222. According to some embodiments of inventive concepts, the second semiconductor layer 222 may be in contact with the third semiconductor layer 223. According to some embodiments of inventive concepts, the second semiconductor layer 222 may include an opening that exposes a top surface of the first semiconductor layer 221. According to some embodiments of inventive concepts, the third semiconductor layer 223 may partially contact the first semiconductor layer 221, through the opening.

According to some embodiments of inventive concepts, the first through third semiconductor layers 221, 222, and 223 may include polysilicon. According to some embodiments of inventive concepts, the first through third semiconductor layers 221, 222, and 223 may include doped polysilicon films. According to some embodiments of inventive concepts, the first through third semiconductor layers 221, 222, and 223 may be doped at substantially the same concentration, without being limited thereto.

The first through third semiconductor layers 221, 222, and 223 may be a substrate of an epitaxial thin film obtained by performing selective epitaxial growth (SEG). The first through third semiconductor layers 221, 222, and 223 may include, for example, at least one of silicon (Si), germanium (Ge), silicon germanium (SiGe), gallium arsenide (GaAs), indium gallium arsenide (InGaAs), aluminum gallium arsenide (AlGaAs), or a mixture thereof.

According to some embodiments of inventive concepts, the gate electrodes 240 may correspond to gates of transistors shown in FIG. 3. More specifically, a gate electrode 240(GE) of a bottom layer may operate as a gate of a ground selection transistor, a gate electrode 240(SE) of a top layer may operate as a gate of a string selection transistor, and gate electrodes 240(WE) arranged therebetween may operate as gates of the plurality of memory cells. Referring to FIG. 6A, it is illustrated that eight gate electrodes 240 operate as gates of memory cells, without being limited thereto. For example, various numbers of, e.g., 4, 16, 32, 64, or 128, gate electrodes 240 may operate as the gates of the memory cells.

According to some embodiments of inventive concepts, one or more dummy gate electrodes may be further arranged between the gate electrodes 240(GE) corresponding to the ground selection transistor and the gate electrodes 240(WE) corresponding to the memory cell and/or between the gate electrodes 240(SE) corresponding to the string selection transistor and the gate electrodes 240(WE) corresponding to the memory cell. In this case, intercell interference occurring between the adjacent gate electrodes 240 may be alleviated.

According to some embodiments of inventive concepts, the gate electrodes 240 may include a conductive material. According to some embodiments of inventive concepts, as shown in FIG. 11, the gate electrodes 240 may include a plurality of layers. According to some embodiments of inventive concepts, the gate electrodes 240 may include tungsten, tantalum, cobalt, nickel, tungsten silicide, tantalum silicide, cobalt silicide, or nickel silicide. According to some embodiments of inventive concepts, the gate electrodes 240 may include polysilicon.

According to some embodiments of inventive concepts, first and second bit line contact vias 271 and 275, an upper conductive pattern 273, and a bit line BL may include any one or more of the materials described above to describe the gate electrodes 240.

According to some embodiments of inventive concepts, the first upper insulation film 261 and the second upper insulation film 263 may be arranged on the gate electrode 240(SE) of the top layer. The first and second upper insulation films 261 and 263 may include an insulation material.

According to some embodiments of inventive concepts, the plurality of channel structures 250 may pass through the first upper insulation film 261, the gate electrodes 240, and the insulation films 230 in the Z direction. According to some embodiments of inventive concepts, the channel structures 250 may pass through the third semiconductor layer 223. According to some embodiments of inventive concepts, a lower portion of the channel structures 250 may be surrounded by the first semiconductor layer 221. Thus, the top surfaces of the channel structures 250 may be coplanar with the first upper insulation film 261, and the bottom surfaces of the channel structures 250 may be at a lower level than the top surface of the first semiconductor layer 221. Adjacent channel structures may be separated by a specific interval in the X direction and the Y direction.

According to some embodiments of inventive concepts, each of the channel structures 250 may include a plurality of layers. According to some embodiments of inventive concepts, each of the channel structures 250 may include a gate insulation film 251, a channel layer 253, and a buried insulation film 255.

According to some embodiments of inventive concepts, the gate insulation film 251 may have a conformal thickness. According to some embodiments of inventive concepts, the gate insulation film 251 may form a bottom surface and an outer surface of the channel structure 250. Thus, according to some embodiments of inventive concepts, the gate insulation film 251 may insulate the channel layer 253 from the gate electrodes 240.

According to some embodiments of inventive concepts, the gate insulation film 251 may include a plurality of layers having a conformal thickness. According to some embodiments of inventive concepts, the gate insulation film 251 may include a tunnel insulation layer, a charge trap layer, and a blocking insulation layer. The tunnel insulation layer may include silicon oxide, hafnium oxide, aluminum oxide, zirconium oxide, tantalum oxide, etc. The charge trap layer may be a region in which electrons tunneling from the channel layer 253 are stored, and may include silicon nitride, boron nitride, silicon boron nitride, or polysilicon doped with impurities. The blocking insulation layer may include a single film or a stacked film such as silicon oxide, silicon nitride, hafnium oxide, aluminum oxide, zirconium oxide, tantalum oxide, etc. However, a material of the blocking insulation layer is not limited thereto, and the blocking insulation layer may include a dielectric material having a high dielectric constant.

According to some embodiments of inventive concepts, the gate insulation film 251 may not be arranged in the same level as the second semiconductor layer 222. This is because a part of the gate insulation film 251 is removed in a process of replacement with the second semiconductor layer 222, such that the second semiconductor layer 222 and the channel layer 253 may be connected to each other.

According to some embodiments of inventive concepts, the channel layer 253 may fill a part of an internal space defined by the gate insulation film 251. The channel layer 253 formed on an inner sidewall of the gate insulation film 251 may have a constant thickness. According to some embodiments of inventive concepts, an upper portion of the channel layer 253 may have a greater thickness than a sidewall of the channel layer 253.

According to some embodiments of inventive concepts, the buried insulation film 255 may be filled in a space defined by the channel layer 253. A top surface of the buried insulation layer 255 may be covered with the upper portion of the channel layer 253. According to some embodiments of inventive concepts, a top surface of the channel layer 253 may serve as a pad for forming electrical connection with the first bit line contact vias 271. Depending on cases, a separate contact pad may be provided on the top surface of the channel layer 253.

While the gate insulation film 251 is illustrated as covering a bottom surface of the channel layer 253 in FIG. 11, inventive concepts are not limited thereto. For example, the gate insulation film 251 may expose the bottom surface of the channel layer 253 and form a sidewall of the channel structure 250. In this case, a semiconductor pattern grown in a process of selective epitaxial growth and the bottom surface of the channel layer may contact each other, and the channel layer may not be directly connected to the first, second, and third semiconductor layers 221, 222, and 223.

According to some embodiments of inventive concepts, the word line cut insulation film WLCI may pass through the first upper insulation film 261, the second upper insulation film 263, the gate electrodes 240, and the insulation films 230 in the Z direction. According to some embodiments of inventive concepts, the word line cut insulation film WLCI may pass through a part of the first semiconductor layer 221, without being limited thereto. According to some embodiments of inventive concepts, the word line cut insulation film WLCI may insulate different gate electrodes 240 arranged in the same vertical level from each other. According to some embodiments of inventive concepts, the word line cut insulation film WLCI may extend longitudinally in the X direction to separate the gate electrodes 240 in the X direction. The X-direction length of the word line cut insulation film WLCI may be greater than the X-direction length of the gate electrodes 240. Thus, the word line cut insulation film WLCI may completely separate the gate electrodes 240. Thus, the gate electrodes 240 that are horizontally separated may operate as gates of different transistors (e.g., a ground selection transistor, a memory cell transistor, and/or a string selection transistor).

According to some embodiments of inventive concepts, the word line cut insulation film WLCI may have a tapered shape in the Z direction. Herein, the tapered shape may denote a shape in which a horizontal width linearly decreases toward the first through third semiconductor layers 221, 222, and 223. According to some embodiments of inventive concepts, the word line cut insulation film WLCI may include a part having a width (e.g., a Y-direction width) that decreases in the Z direction. The word line cut insulation film WLCI may have a structure protruding in the horizontal direction (e.g., the Y direction) in the same level as the gate electrodes 240. Thus, a part of the word line cut insulation film WLCI, arranged in the same level as the gate electrode 240, may have a wider width than a part of the word line cut insulation film WLCI, arranged in the same level as the insulation film 230 adjacent to the gate electrode 240. The above-described structure of the word line cut insulation film WLCI may be formed by recessing gate electrode materials in a node separation process.

According to some embodiments of inventive concepts, the word line cut insulation film WLCI may include an insulation material such as silicon oxide, silicon nitride, silicon oxynitride, etc.

The third upper insulation film 265 may divide the gate electrode 240(SE) of the top layer between the adjacent word line cut insulation films WLCI into three parts, without being limited thereto. For example, the third upper insulation film 265 may divide the gate electrode 240(SE) of the top layer between the adjacent word line cut insulation films WLCI into four or more parts.

The third upper insulation film 265 may be arranged on the second upper insulation film 263. The third upper insulation film 265 may include an insulation material. According to some embodiments of inventive concepts, the first bit line contact vias 271 and the second bit line contact vias 275 may extend in the Z direction in the same level as at least a part of the third upper insulation film 265. According to some embodiments of inventive concepts, the first bit line contact vias 271 may further pass through the second upper insulation film 263. According to some embodiments of inventive concepts, the first bit line contact vias 271 may contact the channel layer 253. According to some embodiments of inventive concepts, the upper conductive pattern 273 may be arranged between the first bit line contact vias 271 and the second bit line contact vias 275. According to some embodiments of inventive concepts, the upper conductive pattern 273 may extend in the horizontal direction (e.g., the X direction and/or the Y direction). According to some embodiments of inventive concepts, the upper conductive pattern 273 may contact the first bit line contact vias 271 and the second bit line contact vias 275. According to some embodiments of inventive concepts, the bit line BL may contact the second bit line contact vias 275.

According to some embodiments of inventive concepts, the channel structures 250 may be connected to the bit line BL through the first bit line contact vias 271, the upper conductive pattern 273, and the second bit line contact vias 275.

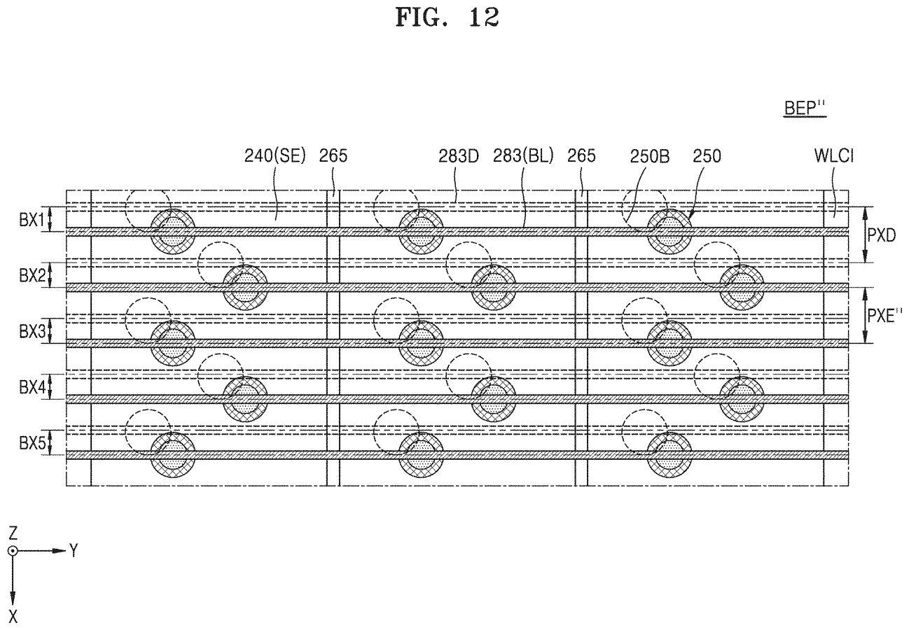

FIG. 12 is a plane view of a part BEP″ of the edge portion BEP″ of FIG. 9.

According to embodiments of inventive concepts, a top surface of each of the channel structures 250 of the part BEP″ may be offset from a designed position 250B. Thus, the gradual bias may be applied to bit lines 283(BL) in the X direction perpendicular to the Y direction that is an extending direction of the bit lines 283(BL). According to embodiments of inventive concepts, the gradual bias may not be applied in the Y direction that is an extending direction of the bit lines 283(BL), without being limited thereto.

For example, the bit lines 283(BL) may be moved by X-direction biases BX1, BX2, BX3, BX4, and BX5 from a designed position 283D. The X-direction biases BX1, BX2, BX3, BX4, and BX5 may sequentially decrease in magnitude. For example, the X-direction bias BX1 may be greater than the X-direction bias BX2, and the X-direction bias BX2 may be greater than the X-direction bias BX3. Thus, an X-direction pitch PXE″ of the bit lines 283(BL) may be less than an X-direction pitch PXD of the designed position 283D and a pitch PXC″ of the bit lines 283(BL) of the part BCP″ shown in FIG. 10.

While inventive concepts have been particularly shown and described with reference to embodiments thereof, it will be understood that various changes in form and details may be made therein without departing from the spirit and scope of the following claims.

What is claimed is:

1. A semiconductor device comprising:
a substrate;
a plurality of lower electrodes on the substrate, the plurality of lower electrodes extending in a first direction perpendicular to a top surface of the substrate; and
a support structure having a flat panel shape, the support structure contacting a side surface of the plurality of lower electrodes and supporting the plurality of lower electrodes, the support structure including a plurality of openings,
the support structure including a first part and a second part, the first part including the plurality of openings repeated by a first pitch, and the second part including the plurality of openings repeated by a second pitch that is different from the first pitch.

2. The semiconductor device of claim 1, wherein
the first part horizontally surrounds the second part, and
the first pitch is less than the second pitch.

3. The semiconductor device of claim 2, wherein
the support structure further comprises a third part between the first part and the second part,
the third part includes the plurality of openings repeated by a third pitch that is greater than the first pitch and less than the second pitch.

4. The semiconductor device of claim 1, wherein
the plurality of lower electrodes are arranged in a honeycomb structure, and
centers of the plurality of openings overlap centers of first diamonds formed by centers of top surfaces of four adjacent lower electrodes among the plurality of lower electrodes in the first direction.

5. The semiconductor device of claim 4, wherein the centers of the plurality of openings are horizontally separated from centers of second diamonds formed by centers of bottom surfaces of the four adjacent lower electrodes among the plurality of lower electrodes.

6. The semiconductor device of claim 5, wherein
the plurality of openings include a first opening and a second opening,
the second opening is closer to the support structure than the first opening,
a first bias is a horizontal distance between a center of the first opening and a corresponding one of the centers of the second diamonds,
a second bias is a horizontal distance between a center of the second opening and an other corresponding one of the centers of the second diamonds, and
the first bias is greater than the second bias.

7. The semiconductor device of claim 1, wherein
the plurality of lower electrodes are arranged in a honeycomb structure, and
centers of the plurality of openings overlap centers of first regular triangles formed by centers of top surfaces of three adjacent lower electrodes among the plurality of lower electrodes in the first direction.

8. The semiconductor device of claim 7, wherein
the centers of the plurality of openings are horizontally separated from centers of second regular triangles formed by centers of bottom surfaces of three adjacent lower electrodes among the plurality of lower electrodes.

9. A semiconductor device comprising:
a plurality of blocks,
each of the plurality of blocks being a set memory unit and including a plurality of lower electrodes and a support structure,
the plurality of lower electrodes extending in a first direction,
the support structure having a flat panel shape,
the support structure contacting a side surface of the plurality of lower electrodes and supporting the plurality of lower electrodes,
the support structure including a plurality of openings,
each of plurality of blocks having a center portion where the plurality of openings are repeated by a first pitch and an edge portion where the plurality of opening are repeated by a second pitch,
the first pitch being less than the second pitch, and
the edge portion surrounding the center portion.

10. The semiconductor device of claim 9, wherein the plurality of blocks comprise:
a plurality of internal blocks arranged to form a matrix; and
a plurality of edge blocks horizontally surrounding the plurality of internal blocks.

11. The semiconductor device of claim 10, wherein
the first pitch of the plurality of internal blocks is equal to the first pitch of the plurality of edge blocks, and
the second pitch of the plurality of internal blocks is equal to the second pitch of the plurality of edge blocks.

12. The semiconductor device of claim 10, wherein
the plurality of lower electrodes are arranged in a honeycomb structure, and
the plurality of openings of the center portion of the plurality of internal blocks each overlap corresponding centers of diamonds formed by centers of bottom surfaces of four adjacent lower electrodes among the plurality of lower electrodes, and
the plurality of openings of the edge portion of the plurality of internal blocks each are horizontally separated from corresponding centers of the diamonds.

13. The semiconductor device of claim 12, wherein the centers of the plurality of openings of the center portion of the plurality of edge blocks each are horizontally separated from corresponding centers of the diamonds.

14. The semiconductor device of claim 12, wherein the centers of the plurality of openings of the center portion of the plurality of internal blocks each overlap corresponding centers of the diamonds in a first direction.

15. The semiconductor device of claim 12, wherein the plurality of edge blocks comprise:
first edge blocks arranged in a second direction perpendicular to the first direction; and
second edge blocks arranged in a third direction perpendicular to the first direction and the second direction, and
the centers of the openings of the center portion of the first edge blocks each are separated from corresponding centers of the diamonds in the third direction.

16. The semiconductor device of claim 15, wherein the centers of the openings of the center portion of the second edge blocks each are separated from corresponding centers of the diamonds in the second direction.

17. The semiconductor device of claim 12, wherein
the plurality of openings include a first opening and a second opening,
the second opening is closer to the center portion than the first opening,
a first bias is a horizontal distance between a center of the first opening and a corresponding one of centers of the diamonds,
a second bias is a horizontal distance between a center of the second opening and an other corresponding one of the centers of the diamonds, and
the first bias is greater than the second bias.

18. A semiconductor device comprising:
a substrate;
a plurality of gate electrodes stacked on the substrate in a first direction perpendicular to a top surface of the substrate;
a plurality of insulation films between the plurality of gate electrodes;
a plurality of channel structures passing through the plurality of gate electrodes and the plurality of insulation films; and
a plurality of bit lines extending in a second direction parallel to the top surface of the substrate on the plurality of channel structures, the plurality of bit lines connected to at least a part of the plurality of channel structures,
the plurality of bit lines including first bit lines and second bit lines,
the first bit lines being repeated with a first pitch in a third direction that is perpendicular to the first direction and the second direction, and
the second bit lines being repeated with a second pitch that is different from the first pitch in the third direction.

19. The semiconductor device of claim 18, further comprising:
a plurality of blocks having a same circuit design,
wherein the first bit lines are in a center portion of the plurality of blocks, the second bit lines are in an edge portion of the plurality of blocks, and the edge portion surrounds the center portion.

20. The semiconductor device of claim 19, wherein the first pitch is greater than the second pitch.
